(19) United States
(12) Patent Application Publication
(10) Pub. No.: US 2026/0050215 A1
(43) Pub. Date: Feb. 19, 2026

(54) MATERIAL FOR FORMING SUPERFINE PATTERN, PHOTOSENSITIVE RESIN COMPOSITION, PATTERN TREATMENT COMPOSITION AND FORMATION METHOD OF SUPERFINE PATTERN

(71) Applicant: Advanced Echem Materials Company Limited, Taoyuan (TW)

(72) Inventors: Kuan-Ming Chen, Taoyuan (TW); Chi-Yu Lai, Taoyuan (TW)

(73) Assignee: Advanced Echem Materials Company Limited, Taoyuan (TW)

(21) Appl. No.: 19/294,247

(22) Filed: Aug. 7, 2025

(30) Foreign Application Priority Data
Aug. 13, 2024 (TW) 113130253

(51) Int. Cl. G03F 7/008; G03F 7/11; G03F 7/38

(52) U.S. Cl. CPC G03F 7/0085; G03F 7/11; G03F 7/38

(57) ABSTRACT

A material for forming a superfine pattern, a photosensitive resin composition, a pattern treatment composition and a formation method of superfine pattern are provided. The material for forming a superfine pattern includes a first layer and a second layer. The first layer includes a photosensitive resin composition (I). The photosensitive resin composition (I) includes an alkali-soluble phenol formaldehyde resin (A), a sensitizer (B), a hydroxyl-containing additive (C) and an organic solvent (D). The second layer includes a pattern treatment composition (II). The pattern treatment composition (II) includes a crosslinking agent (M), a water-soluble resin (N), a thermal acid generator (P) and water (Q). The hydroxyl-containing additive (C) includes a compound represented by following Formula (C-1). The crosslinking agent (M) includes a melamine-based crosslinking agent.

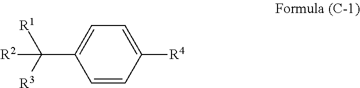

In Formula (C-1), the definition of R¹ to R⁴ is the same as defined in the detailed description.

### CROSS-REFERENCE TO RELATED APPLICATION

This application claims the priority benefit of Taiwan application serial no. 113130253, filed on Aug. 13, 2024. The entirety of the above-mentioned patent application is hereby incorporated by reference herein and made a part of this specification.

### BACKGROUND

### Technical Field

The invention relates to a material for forming a pattern, and particularly to a material for forming a superfine pattern, a photosensitive resin composition, a pattern treatment composition and a formation method of a superfine pattern.

### Description of Related Art

With the flourishing development of semiconductor devices, display devices, and optical elements, the demand for performance and quality has gradually increased to expand their application scope. For example, along with the requirements for high integration and high speed, the miniaturization of patterns in the manufacturing process of devices is extremely important. However, currently exposure equipment is often limited by the limit of wavelength of the light source, which causes the formed pattern shape to be deformed due to, for example, diffraction of the light source, thereby affecting subsequent manufacturing processes (such as etching processes) and the performance of the manufactured devices.

### SUMMARY

The invention provides a material for forming a superfine pattern, a photosensitive resin composition, a pattern treatment composition and a formation method of a superfine pattern capable of providing good resolution.

The material for forming a superfine pattern of the invention includes a first layer and a second layer. The first layer includes a photosensitive resin composition (I). The photosensitive resin composition (I) includes an alkali-soluble phenol formaldehyde resin (A), a sensitizer (B), a hydroxyl-containing additive (C), and an organic solvent (D). The second layer includes a pattern treatment composition (II). The pattern treatment composition (II) includes a crosslinking agent

(M), a water-soluble resin (N), a thermal acid generator (P), and water (Q). The hydroxyl-containing additive (C) includes a compound represented by the following Formula (C-1). The crosslinking agent (M) includes a melamine-based crosslinking agent. Based on 100 parts by weight of the alkali-soluble phenol formaldehyde resin (A) in the photosensitive resin composition (I), a usage amount of the sensitizer (B) is 10 parts by weight to 35 parts by weight, a usage amount of the hydroxyl-containing additive (C) is 2 parts by weight to 15 parts by weight, and a usage amount of the organic solvent (D) is 400 parts by weight to 1200 parts by weight. Based on a total usage amount of the pattern treatment composition (II) being 100 parts by weight, a usage amount of the crosslinking agent (M) is 0.5 parts by weight to 2.5 parts by weight, a usage amount of the water-soluble resin (N) is 2.4 parts by weight to 4.5 parts by weight, a usage amount of the thermal acid generator (P) is 0.02 parts by weight to 0.06 parts by weight, and a usage amount of water (Q) is 90 parts by weight to 98 parts by weight.

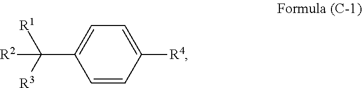

in Formula (C-1),
R¹ to R³ each represents hydrogen, an alkyl group having 1 to 3 carbon atoms, a phenyl group substituted with hydroxyl group or a derivative thereof,
R⁴ represents a hydroxyl group, an alkyl group having 1 to 3 carbon atoms, a phenyl group substituted with hydroxyl and/or alkyl groups or a derivative thereof, and at least one of R¹ to R⁴ represents a hydroxyl-containing substituent.

In an embodiment of the invention, a weight average molecular weight of the alkali-soluble phenol formaldehyde resin (A) in the photosensitive resin composition (I) is 2000 g/mol to 20000 g/mol.

In an embodiment of the invention, the sensitizer (B) in the photosensitive resin composition (I) includes a compound having a quinonediazide group, a hydroxy benzophenone-based compound, a hydroxy aryl-based compound, or a combination thereof.

In an embodiment of the invention, in the pattern treatment composition (II), a usage amount of the crosslinking agent (M) is less than or equal to a usage amount of the water-soluble resin (N).

In an embodiment of the invention, in the pattern treatment composition (II), a weight ratio of a usage amount of the crosslinking agent (M) to a usage amount of the water-soluble resin (N) is 20:80 to 50:50.

In an embodiment of the invention, the crosslinking agent (M) in the pattern treatment composition (II) includes a compound represented by the following Formula (M-1):

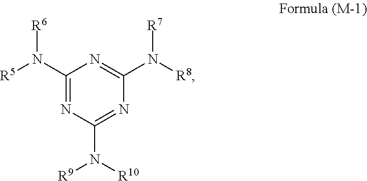

in Formula (M-1), R⁵ to R¹⁰ each represents hydrogen, an alkyl group, or an ether-containing substituent, wherein at least one of R⁵ to R¹⁰ is an ether-containing substituent.

In an embodiment of the invention, the water-soluble resin (N) in the pattern treatment composition (II) includes a polymer represented by the following Formula (N-1):

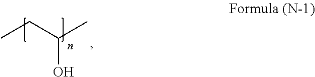

in Formula (N-1), n represents an integer from 1000 to 3000.

In an embodiment of the invention, a weight average molecular weight of the water-soluble resin (N) is 40000 g/mol to 120000 g/mol.

In an embodiment of the invention, the thermal acid generator (P) includes an ionic thermal acid generator.

A photosensitive resin composition of the invention includes an alkali-soluble phenol formaldehyde resin (A), a sensitizer (B), a hydroxyl-containing additive (C), and an organic solvent (D). The hydroxyl-containing additive (C) includes a compound represented by the following Formula (C-1). Based on 100 parts by weight of the alkali-soluble phenol formaldehyde resin (A) in the photosensitive resin composition, a usage amount of the sensitizer (B) is 10 parts by weight to 35 parts by weight, a usage amount of the hydroxyl-containing additive (C) is 2 parts by weight to 15 parts by weight, and a usage amount of the organic solvent (D) is 400 parts by weight to 1200 parts by weight.

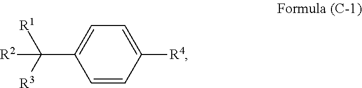

In Formula (C-1),
R¹ to R³ each represents hydrogen, an alkyl group having 1 to 3 carbon atoms, a phenyl group substituted with hydroxyl group or a derivative thereof,
R⁴ represents a hydroxyl group, an alkyl group having 1 to 3 carbon atoms, a phenyl group substituted with hydroxyl and/or alkyl groups or a derivative thereof, and
at least one of R¹ to R⁴ represents a hydroxyl-containing substituent.

A pattern treatment composition of the invention includes a crosslinking agent (M), a water-soluble resin (N), a thermal acid generator (P), and water (Q). The crosslinking agent (M) includes a melamine-based crosslinking agent. Based on a total usage amount of the pattern treatment composition (II) being 100 parts by weight, a usage amount of the crosslinking agent (M) is 0.5 parts by weight to 2.5 parts by weight, a usage amount of the water-soluble resin (N) is 2.4 parts by weight to 4.5 parts by weight, a usage amount of the thermal acid generator (P) is 0.02 parts by weight to 0.06 parts by weight, and a usage amount of water (Q) is 90 parts by weight to 98 parts by weight.

A formation method of a superfine pattern of the invention includes: applying the aforementioned material for forming a superfine pattern on a substrate; and cleaning with a solvent.

In an embodiment of the invention, the formation method of a superfine pattern further includes: applying the photosensitive resin composition of the material for forming a superfine pattern on a substrate to form a cured product; and applying the pattern treatment composition of the material for forming a superfine pattern on the cured product.

A formation method of a superfine pattern of the invention includes: forming a cured product on a substrate, wherein the cured product is formed by the aforementioned photosensitive resin composition; coating a pattern treatment composition on the cured product; and cleaning with a solvent.

A formation method of a superfine pattern of the invention includes: forming a cured product on a substrate, wherein the cured product is formed by a photosensitive resin composition; coating the aforementioned pattern treatment composition on the cured product; and cleaning with a solvent.

Based on the above, the material for forming a superfine pattern of the invention includes a first layer containing a photosensitive resin composition (I) with a specific composition and a second layer containing a pattern treatment composition (II) with a specific composition, and the usage amount of each component is within a specific range. As a result, the material for forming a superfine pattern used in a formation method of a superfine pattern may have good resolution.

To make the above features and advantages of the invention more apparent and understandable, embodiments are described in detail below.

### DESCRIPTION OF THE EMBODIMENTS

### <Material for Forming Superfine Pattern>

The invention provides a material for forming a superfine pattern, including a first layer containing a photosensitive resin composition (I) and a second layer containing a pattern treatment composition (II). In addition, the photosensitive resin composition (I) and the pattern treatment composition (II) of the invention may each further include other additives according to needs. The components are described hereinafter in detail.

### <Photosensitive Resin Composition (I)>

According to this embodiment, a photosensitive resin composition (I) includes an alkali-soluble phenol formaldehyde resin (A), a sensitizer (B), a hydroxyl-containing additive (C), and an organic solvent (D). The preparation method of the photosensitive resin composition (I) is not particularly limited. For example, the alkali-soluble phenol formaldehyde resin (A), sensitizer (B), hydroxyl-containing additive (C), and organic solvent (D) may be placed in a stirrer and mixed uniformly into a solution state. Other additives may also be added if necessary. After mixing them uniformly, a liquid photosensitive resin composition may be obtained.

### Alkali-Soluble Phenol Formaldehyde Resin (A)

The alkali-soluble phenol formaldehyde resin (A) is not particularly limited, and any suitable alkali-soluble phenol formaldehyde resin may be selected according to needs. The alkali-soluble phenol formaldehyde resin (A) may be used alone or in combination with multiple types. For example, the alkali-soluble phenol formaldehyde resin (A) may be prepared by polycondensation reaction of a phenolic compound with an aldehydic compound using a catalyst. The phenolic compound may include a cresol-based compound, a xylenol-based compound, a trimethylphenol-based compound, a tert-butylphenol-based compound, a methoxyphenol-based compound, an ethylphenol-based compound, a chlorophenol-based compound, a resorcinol-based compound, a catechol-based compound, a pyrogallol-based compound, a bisphenol-based compound, a hydroxymethylated cresol-based compound, a naphthol-based compound, or other suitable phenolic compounds. The cresol-based compound may include o-cresol, m-cresol, p-cresol, or other suitable cresol-based compounds. The xylenol-based compound may include 3,5-xylenol, 2,5-xylenol, 2,3-xylenol, 3,4-xylenol, or other suitable xylenol-based compounds. The trimethylphenol-based compound may include 2,3,4-trimethylphenol, 2,3,5-trimethylphenol, 2,4,5-trimethylphenol, 3,4,5-trimethylphenol, or other suitable trimethylphenol-based compounds. The tert-butylphenol-based compound may include 2-tert-butylphenol, 3-tert-butylphenol, 4-tert-butylphenol, or other suitable tert-butylphenol-based compounds. The methoxyphenol-based compound may include 2-methoxyphenol, 3-methoxyphenol, 4-methoxyphenol, 2,3-dimethoxyphenol, 2,5-dimethoxyphenol, 3,5-dimethoxyphenol, or other suitable methoxyphenol-based compounds. The ethylphenol-based compound may include 2-ethylphenol, 3-ethylphenol, 4-ethylphenol, 2,3-diethylphenol, 3,5-diethylphenol, 2,3,5-triethylphenol, 3,4,5-triethylphenol, or other suitable ethylphenol-based compounds. The chlorophenol-based compound may include o-chlorophenol, m-chlorophenol, p-chlorophenol, 2,3-dichlorophenol, or other suitable chlorophenol-based compounds. The resorcinol-based compound may include resorcinol, 2-methylresorcinol, 4-methylresorcinol, 5-methylresorcinol, or other suitable resorcinol-based compounds. The catechol-based compound may include 5-methylcatechol or other suitable catechol-based compounds. The pyrogallol-based compound may include 5-methylpyrogallol or other suitable pyrogallol-based compounds. The bisphenol-based compound may include bisphenol A, bisphenol B, bisphenol C, bisphenol D, bisphenol E, bisphenol F, or other suitable bisphenol compounds. The hydroxymethylated cresol-based compound may include 2,6-di (hydroxymethyl)-p-cresol or other suitable hydroxymethylated cresol-based compounds. The naphthol-based compound may include a-naphthol, B-naphthol, or other suitable naphthol-based compounds. The phenolic compound may be used alone or in combination with multiple types. In this embodiment, the phenolic compound is preferably a cresol-based compound. The cresol-based compound is preferably p-cresol or m-cresol.

The aldehydic compound may include formaldehyde, salicylaldehyde, paraformaldehyde, acetaldehyde, benzaldehyde, hydroxybenzaldehyde, chloroaldehyde, or other suitable aldehydic compounds. The aldehydic compound may be used alone or in combination with multiple types. In this embodiment, the aldehydic compound is preferably benzaldehyde or hydroxybenzaldehyde.

The catalyst may include an inorganic acid, an organic acid, or other suitable catalysts. The inorganic acid may include hydrochloric acid, sulfuric acid, or other suitable inorganic acids. The organic acid may include ethanedioic acid (oxalic acid), acetic acid, or other suitable organic acids. The catalyst may be used alone or in combination with multiple types. In this embodiment, the catalyst is preferably an organic acid, more preferably oxalic acid or acetic acid.

In this embodiment, a weight average molecular weight of the alkali-soluble phenol formaldehyde resin (A) may be 2000 g/mol to 30000 g/mol, preferably 4000 g/mol to 20000 g/mol.

### Sensitizer (B)

The sensitizer (B) is not particularly limited, and any suitable sensitizer may be selected according to needs. For example, the sensitizer (B) may include a compound having a quinonediazide group, a hydroxy benzophenone-based compound, a hydroxy aryl-based compound, or other suitable sensitizers. The compound having a quinonediazide group may include a compound having a naphthoquinonediazide group, a naphthoquinonediazide sulfonic acid-based ester, or other suitable compounds having a quinonediazide group. The sensitizer (B) may be used alone or in combination with multiple types. In this embodiment, the sensitizer (B) is preferably a compound having a quinonediazide group, more preferably a naphthoquinonediazide sulfonic acid-based ester.

Based on 100 parts by weight of the alkali-soluble phenol formaldehyde resin (A) in the photosensitive resin composition (I), a usage amount of the sensitizer (B) is 10 parts by weight to 35 parts by weight, preferably 20 parts by weight to 30 parts by weight.

### Hydroxyl-Containing Additive (C)

The hydroxyl-containing additive (C) includes a compound represented by the following Formula (C-1). The hydroxyl-containing additive (C) may be used alone or in combination with multiple types.

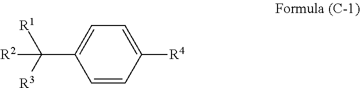

In Formula (C-1),
R¹ to R³ each represents hydrogen, an alkyl group having 1 to 3 carbon atoms, a phenyl group substituted with hydroxyl group or a derivative thereof, preferably a phenyl group substituted with hydroxyl group or an alkyl group having 1 to 3 carbon atoms;
R⁴ represents a hydroxyl group, an alkyl group having 1 to 3 carbon atoms, a phenyl group substituted with hydroxyl and/or alkyl groups or a derivative thereof, preferably an alkyl group having 1 to 3 carbon atoms or a phenyl group substituted with hydroxyl group or a derivative thereof; and
at least one of R¹ to R⁴ represents a hydroxyl-containing substituent, preferably at least three of them represent substituents containing a hydroxyl group.

The hydroxyl-containing substituent may include a hydroxyl group, a phenyl group substituted with hydroxyl group or a derivative thereof, or a phenyl group substituted with hydroxyl and alkyl groups or a derivative thereof. The phenyl group substituted with hydroxyl group or a derivative thereof may include phenol or a derivative thereof. The phenyl group substituted with hydroxyl and alkyl groups or a derivative thereof may include alkylphenol or a derivative thereof.

For example, the hydroxyl-containing additive (C) may include tris (4-hydroxyphenyl) methane, tris (4-hydroxyphenyl) ethane, tris (4-hydroxyphenyl) propane, tris (3-methyl-4-hydroxyphenyl) methane, tris (3-methyl-4-hydroxyphenyl) ethane, tris (3-methyl-4-hydroxyphenyl) propane, bis(4-hydroxy-2-methylphenyl)-4-hydroxyphenylmethane, bis(4-hydroxy-3-methylphenyl)-4-hydroxyphenylmethane, bis(4-hydroxy-5-methylphenyl)-4-hydroxyphenylmethane, bis(4-hydroxy-2,5-dimethylphenyl)-4-hydroxyphenylmethane, bis(4-hydroxy-3,5-dimethylphenyl)-4-hydroxyphenylmethane, bis(4-hydroxy-2,3,5-trimethylphenyl)-2-hydroxyphenylmethane, bis(4-hydroxy-2,3,5-trimethylphenyl)-3-hydroxyphenylmethane, bis(4-hydroxy-2,3,5-trimethylphenyl)-4-hydroxyphenylmethane, bis(4-hydroxy-2,3,5-trimethylphenyl)-4-hydroxyphenylethane, bis(4-hydroxy-2,3,5-trimethylphenyl)-4-hydroxyphenylpropane, (3,4-dihydroxyphenyl)-(4-hydroxyphenyl)phenylmethane, (3,4-dihydroxyphenyl)-(4-hydroxyphenyl)phenylethane, (3,4-dihydroxyphenyl)-(4-hydroxyphenyl)phenylpropane or other suitable hydroxyl-containing additives.

Based on 100 parts by weight of the alkali-soluble phenol formaldehyde resin (A) in the photosensitive resin composition (I), a usage amount of the hydroxyl-containing additive (C) is 2 parts by weight to 15 parts by weight, preferably 5 parts by weight to 10 parts by weight.

When the photosensitive resin composition (I) includes the hydroxyl-containing additive (C), it may enable the material for forming a superfine pattern including the photosensitive resin composition (I) to have good superfine pattern forming ability when used in a formation method of superfine pattern, thereby providing good resolution.

### Organic Solvent (D)

The organic solvent (D) is not particularly limited, and any suitable organic solvent may be selected according to needs. For example, the organic solvent (D) may include propylene glycol monomethyl ether acetate (2-acetoxy-1-methoxypropane, PGMEA), propylene glycol monomethyl ether, diethylene glycol methyl ether, or other suitable organic solvents. The organic solvent (D) may be used alone or in combination with multiple solvents. In this embodiment, the organic solvent (D) is preferably propylene glycol monomethyl ether acetate.

Based on 100 parts by weight of the alkali-soluble phenol formaldehyde resin (A) in the photosensitive resin composition (I), a usage amount of the organic solvent (D) is 400 parts by weight to 1200 parts by weight, preferably 400 parts by weight to 800 parts by weight.

When the photosensitive resin composition (I) includes the organic solvent (D), it may provide the photosensitive resin composition with an appropriate viscosity, thereby achieving good coating uniformity to form a cured product with good surface flatness.

### <Pattern Treatment Composition (II)>

According to this embodiment, a pattern treatment composition (II) includes a crosslinking agent (M), a water-soluble resin (N), a thermal acid generator (P), and water (Q). The preparation method of the pattern treatment composition (II) is not particularly limited. For example, the crosslinking agent (M), water-soluble resin (N), thermal acid generator (P), and water (Q) may be placed in a stirrer and mixed uniformly into a solution state. Other additives may also be added if necessary. After mixing them uniformly, a liquid pattern treatment composition may be obtained.

### Crosslinking Agent (M)

The crosslinking agent (M) includes a melamine-based crosslinking agent. In this embodiment, the crosslinking agent (M) may include a compound represented by the following Formula (M-1). The crosslinking agent (M) may be used alone or in combination with multiple agents.

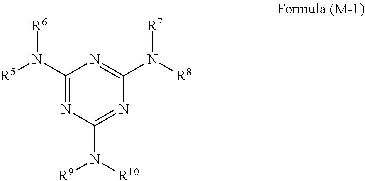

In Formula (M-1), R⁵ to R¹⁰ each represents hydrogen, an alkyl group, or an ether-containing substituent, wherein at least one of R⁵ to R¹⁰ is an ether-containing substituent. The ether-containing substituent may include ethyl ether, aryl-group ether, or other suitable substituents.

For example, the crosslinking agent (M) having hydrogen, an alkyl group, or an ether-containing substituent may include melamine, N²-methyl-melamine, N²,N²-dimethyl-melamine, N²,N²,N⁴-trimethyl-melamine, N²,N²,N⁴,N⁴-tetramethyl-melamine, N²,N²,N⁴,N⁴, N⁶-pentamethyl-melamine, altretamine (a melamine derivative), N²-(methoxymethyl)-melamine, N²-(methoxymethyl)-melamine, N²-(methoxybutyl)-melamine, N²,N⁴-di(methoxymethyl)-melamine, N²,N⁴,N⁶-tri(methoxymethyl)-melamine, N²,N²,N⁴,N⁴,N⁶,N⁶-hexa(methoxymethyl)-melamine, N²-(2-ethoxyethyl)-melamine, N²-(2-phenoxyethyl)-melamine, N²,N⁴-di (2-phenoxyethyl)-melamine or other suitable crosslinking agents.

Based on a total usage amount of the pattern treatment composition (II) being 100 parts by weight, a usage amount of the crosslinking agent (M) is 0.5 parts by weight to 2.5 parts by weight, preferably 0.8 parts by weight to 2.5 parts by weight.

When the pattern treatment composition (II) includes the crosslinking agent (M), it may enable the material for forming a superfine pattern including the pattern treatment composition to have good superfine pattern forming ability when used in a formation method of superfine pattern, thereby providing good resolution.

### Water-Soluble Resin (N)

The water-soluble resin (N) is not particularly limited, and any suitable water-soluble resin may be selected according to needs. For example, the water-soluble resin (N) may include polyvinyl alcohol or other suitable water-soluble resins. In this embodiment, the water-soluble resin (N) may include a polymer represented by the following Formula (N-1).

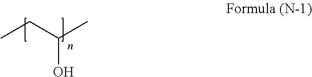

In Formula (N-1), n indicates an integer from 1000 to 3000, preferably an integer from 2500 to 3000.

In this embodiment, a weight average molecular weight of the water-soluble resin (N) may be 40000 g/mol to 120000 g/mol, preferably 110000 g/mol to 120000 g/mol.

Based on a total usage amount of the pattern treatment composition (II) being 100 parts by weight, a usage amount of the water-soluble resin (N) is 2.4 parts by weight to 4.5 parts by weight, preferably 2.4 parts by weight to 4.0 parts by weight.

In the pattern treatment composition (II), a usage amount of the crosslinking agent (M) may be less than or equal to a usage amount of the water-soluble resin (N). A weight ratio of the usage amount of the crosslinking agent (M) to the usage amount of the water-soluble resin (N) may be 20:80 to 50:50, preferably 20:80 to 30:70.

When the relationship between the usage amount of the crosslinking agent (M) and the usage amount of the water-soluble resin (N) in the pattern treatment composition (II) meets the above conditions, it may enable the material for forming a superfine pattern including the pattern treatment composition to have good superfine pattern forming ability when used in a formation method of superfine pattern, thereby providing good resolution.

### Thermal Acid Generator (P)

The thermal acid generator (P) is not particularly limited, and any suitable thermal acid generator may be selected according to needs.

For example, the thermal acid generator (P) may include an ionic thermal acid generator such as a salt formed by sulfonium group and hexafluoroantimonic acid, a salt formed by sulfonium group and tetrafluorophosphoric acid, a salt formed by sulfonium group and tetrakis (pentafluorophenyl) boric acid, or other suitable thermal acid generators. The thermal acid generator (P) may be used alone or in combination with multiple types. In this embodiment, the thermal acid generator (P) is preferably an ionic thermal acid generator.

Based on a total usage amount of the pattern treatment composition (II) being 100 parts by weight, a usage amount of thermal acid generator (P) is 0.02 parts by weight to 0.06 parts by weight, preferably 0.03 parts by weight to 0.05 parts by weight.

When the pattern treatment composition (II) includes a thermal acid generator (P), it may enable the material for forming a superfine pattern including the pattern treatment composition to have good superfine pattern forming ability when used in a formation method of superfine pattern. The mechanism of action of the thermal acid generator (P) is to generate acid upon heating. The acid generated by heating may act as a catalyst to promote the crosslinking agent in the pattern treatment composition to react at the portion where the pattern treatment composition is in contact with the photosensitive resin composition, thereby forming crosslinks. Subsequently, the uncrosslinked pattern treatment composition is removed by development and cleaning. Due to the crosslinking between the pattern treatment composition and the photosensitive resin composition, the pattern widens, thereby leading to a reduction in the opening of the pattern. The pattern opening miniaturization may be achieved through the above reaction, thereby providing good resolution.

### Water (Q)

The water (Q) is not particularly limited, and any suitable water may be selected according to needs. For example, the water (Q) may include deionized water (DI water), ultrapure water, pure water, distilled water, or other suitable water. In this embodiment, the water (Q) is preferably deionized water.

Based on a total usage amount of the pattern treatment composition (II) being 100 parts by weight, a usage amount of water (Q) is 90 parts by weight to 98 parts by weight, preferably 93 parts by weight to 97 parts by weight.

In the material for forming a superfine pattern, the photosensitive resin composition (I) and the pattern treatment composition (II) are used in combination. The photosensitive resin composition (I) and the pattern treatment composition (II) are not mixed for use. A ratio of a usage amount of the photosensitive resin composition (I) to a usage amount of the pattern treatment composition (II) is 0:100 to 100:0, and the usage amount of each of them is not zero.

### <Formation Method of Superfine Pattern>

An exemplary embodiment of the invention provides a formation method of a superfine pattern using the above-mentioned material for forming a superfine pattern, the above-mentioned photosensitive resin composition, and/or the above-mentioned pattern treatment composition.

The formation method of a superfine pattern may include forming a cured product on a substrate and cleaning with a solvent. The step of forming a cured product on the substrate may include applying the material for forming a superfine pattern on the substrate. For example, the photosensitive resin composition from the material for forming a superfine pattern may be first applied on the substrate to form a cured product; then, the pattern treatment composition from the material for forming a superfine pattern may be applied on the cured product formed by the photosensitive resin composition.

The photosensitive resin composition may be applied on the substrate by a coating method to form a coating film, and the coating film is dried, exposed, developed, and post-baked to form a cured product. For example, after coating the photosensitive resin composition on the substrate to form a coating film, performing vacuum to 20˜1500 Pa, and performing a baking step (i.e., pre-baking) at a temperature of 80˜120° C. for 90˜180 seconds before exposure to dry the photosensitive resin composition to form a photoresist film with a thickness of 0.8˜2.8 micrometers. Next, use an exposure machine to expose the photoresist film with light at 8˜50 J/m². Then, perform a development step on the exposed photoresist film for 40˜80 seconds. Next, post-bake at a temperature of 100˜120° C. for 120˜300 seconds to form a cured product with a pattern of 4 micrometers on the substrate.

The pattern treatment composition may be applied on the cured product by a coating method to form a coating film, and the coating film is dried, post-baked, developed, and cleaned to form a treated cured product. For example, the pattern treatment composition was directly coated on the cured product with a pattern, and baked at a temperature of 60˜70° C. for 60˜120 seconds to dry the pattern treatment composition to form an initial film with a thickness of 0.4˜0.8 micrometers. Next, bake the initial film at a temperature of 100˜120° C. for 60˜120 seconds to allow the initial film to undergo a crosslinking reaction with the cured product. Then, perform a development step on the crosslinked initial film for 50˜100 seconds to dissolve the non-crosslinked initial film. Next, perform a cleaning step using a solvent for 100˜150 seconds to remove the non-crosslinked initial film and pattern treatment composition.

The substrate may be a glass substrate, plastic base material (for example, polyethersulfone (PES) plate, polycarbonate (PC) plate, or polyimide (PI) film), or other light-transmitting substrates. There is no particular limitation on the type of substrate.

The coating method is not particularly limited, but spray coating, roll coating, spin coating, or similar methods may be used, and generally, spin coating is widely used. Furthermore, a coating film is formed, and subsequently, in some cases, residual solvent may be partially removed under reduced pressure.

The developer is not particularly limited, and any suitable developer may be selected according to needs. For example, the developer may be a tetramethylammonium hydroxide (TMAH) aqueous solution, for which a concentration thereof may be 2.38 weight %.

Hereinafter, the invention will be described in detail with reference to examples. The following examples are provided to describe the present invention, and the scope of the invention includes the scope stated in the following claims and their substitutes and modifications, and is not limited to the scope of the examples.

### Synthesis Example 1: Preparation of Alkali-Soluble Phenol Formaldehyde Resin

A 10 L four-neck separable reaction vessel was equipped with a nitrogen inlet, stirrer, heater, and condenser, and nitrogen was introduced for 30 minutes. Then, 0.5 moles of p-cresol, 0.5 moles of m-cresol, 1.0 mole of benzaldehyde, and 0.015 moles of oxalic acid were added. Next, the mixture was slowly stirred for 8 hours and heated to 90° C. to allow the reactants to undergo a condensation reaction at this temperature. Then, the solution was heated to 170° C. and vacuum dried at a pressure of 10 mmHg. After the solvent evaporated, an alkali-soluble phenol formaldehyde resin (A-1) with a weight average molecular weight of about 10000 g/mol was obtained.

### Synthesis Example 2: Preparation of Sensitizer

0.5 moles of α,α,α′-tris (4-hydroxyphenyl)-1-ethyl-4-isopropylbenzene (TrisP-PA) and 1.5 moles of naphthoquinone-1,2-diazide-5-sulfonyl chloride were dissolved in dimethylacetamide to form a reaction solution. Then, the reaction solution was cooled to 30° C. using ice. Next, 0.15 moles of triethylamine was added to the reaction solution as a basic catalyst to allow the reaction solution to react for 2 hours. Then, the triethylamine was filtered out, and the filtrate was poured into water to produce a precipitate. Next, the precipitate was collected by washing with water for 3 times. Then, the solution including the precipitate was heated to 60° C. and vacuum dried at a pressure of 10 mmHg. After drying, the sensitizer (B-1) was obtained.

### <Preparation of Photosensitive Resin Composition (I)>

The photosensitive resin compositions I-1 to photosensitive resin composition I-3 are described hereinafter.

### Photosensitive Resin Composition I-1

100 parts by weight of alkali-soluble phenol formaldehyde resin (A-1), 24.8 parts by weight of sensitizer (B-1), and 6.5 parts by weight of hydroxyl-containing additive (C-1) were added to 465 parts by weight of propylene glycol monomethyl ether acetate. And after stirring uniformly with a stirrer and filtering, the photosensitive resin composition I-1 was obtained.

### Photosensitive Resin Composition I-2 to Photosensitive Resin Composition I-3

Photosensitive resin composition I-2 to photosensitive resin composition I-3 were prepared using the same procedure as photosensitive resin composition I-1. The difference is that the types of components and the usage amount thereof in the photosensitive resin composition are changed (as shown in Table 2), wherein the compounds in Table 2 are shown as in Table 1.

TABLE 1

| | Symbol | Component/compound |
|---|---|---|
| Alkali-soluble | A-1 | An alkali-soluble phenol formaldehyde resin prepared by |
| phenol | | Synthesis Example 1. |
| formaldehyde | | |
| resin (A) | | |
| Sensitizer (B) | B-1 | A sensitizer prepared by Synthesis Example 2. |
| Hydroxyl- containing additive (C) | C-1 | A compound represented by the following Formula (C-1-1). 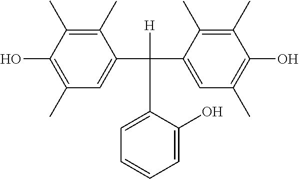 [SMILES: Cc1cc(C(c2ccccc2O)c2cc(C)c(O)c(C)c2C)c(C)c(C)c1O] |
| | | Formula (C-1-1) |
| | C-2 | A compound represented by the following Formula (C-1-2). |
| | | 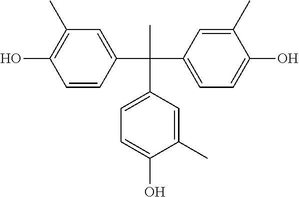 [SMILES: Cc1cc(C(C)(c2ccc(O)c(C)c2)c2ccc(O)c(C)c2)ccc1O] |
| | | Formula (C-1-2) |
| Organic solvent | D-1 | Propylene glycol monomethyl ether acetate (PGMEA) |
| (D) | | |
| Crosslinking | M-1 | Cymel-380 (Product name; manufactured by Allnex LTD.) |
| agent (M) | M-2 | Cymel-373 (Product name; manufactured by Allnex LTD.) |
| | M-3 | Cymel-370 (Product name; manufactured by Allnex LTD.) |
| Water-soluble | N-1 | Polyvinyl alcohol having a weight average molecular weight of about 118000 g/mol. |
| resin (N) | | |
| | N-2 | Polyvinyl alcohol having a weight average molecular weight of about 47000 g/mol. |
| | N-3 | Xanthan gum |
| Thermal acid | P-1 | SI-60L (Product name; manufactured by Sanshin Chemical Ind. Co., Ltd.) |
| generator (P) | | |
| | P-2 | K-PURE ®CXC-1612 (Product name; manufactured by King Industries, Inc. |
| Water (Q) | Q-1 | Deionized water |

TABLE 2

| Component | | Photosensitive resin composition | | |
|---|---|---|---|---|
| (unit: parts by weight) | | I-1 | I-2 | I-3 |
| Alkali-soluble phenol | A-1 | 100 | 100 | 100 |
| formaldehyde resin (A) | | | | |
| Sensitizer (B) | B-1 | 24.8 | 24.8 | 24.8 |
| Hydroxyl-containing additive | C-1 | 6.5 | — | — |
| (C) | C-2 | — | 6.5 | — |
| Organic solvent (D) | D-1 | 465 | 465 | 465 |

### <Preparation of Pattern Treatment Composition (II)>

The pattern treatment composition II-1 to pattern treatment composition II-15 are described hereinafter.

### Pattern Treatment Composition II-1

0.974 parts by weight of crosslinking agent (M-1), 3.897 parts by weight of water-soluble resin (N-1), and 0.039 parts by weight of thermal acid generator (P-1) were added to 95.09 parts by weight of deionized water. And after stirring uniformly with a stirrer, the pattern treatment composition II-1 was obtained.

### Pattern Treatment Composition II-2 to Pattern Treatment Composition II-15

Pattern treatment composition II-2 to pattern treatment composition II-15 were prepared using the same procedure as pattern treatment composition II-1. The difference is that the types of components and the usage amount thereof in the pattern treatment composition are changed (as shown in Table 3), wherein the compounds in Table 3 are shown as in Table 1.

TABLE 3

| Component | | | | | | | | | |
|---|---|---|---|---|---|---|---|---|---|
| (unit: parts by | | Pattern treatment composition | | | | | | | |
| weight) | | II-1 | II-2 | II-3 | II-4 | II-5 | II-6 | II-7 | II-8 |
| Crosslinking | M-1 | 0.974 | 1.218 | 1.461 | 1.948 | 0.974 | 2.435 | — | — |
| agent (M) | M-2 | — | — | — | — | — | — | 2.435 | 1.218 |
| | M-3 | — | — | — | — | — | — | — | — |
| Water- | N-1 | 3.897 | 3.653 | 3.41 | 2.923 | — | — | 2.436 | 3.653 |
| soluble resin | N-2 | — | — | — | — | 3.897 | 2.436 | — | — |
| (N) | N-3 | — | — | — | — | — | — | — | — |
| Thermal acid | P-1 | 0.039 | 0.039 | 0.039 | — | 0.039 | — | — | 0.039 |
| generator (P) | P-2 | — | — | — | 0.039 | — | 0.039 | 0.039 | — |
| Water (Q) | Q-1 | 95.09 | 95.09 | 95.09 | 95.09 | 95.09 | 95.09 | 95.09 | 95.09 |

| | | | | | | | | |
|---|---|---|---|---|---|---|---|---|
| Crosslinking agent | 20:80 | 25:75 | 30:70 | 40:60 | 20:80 | 50:50 | 50:50 | 25:75 |
| (M):Water-soluble | | | | | | | | |
| resin (N) | | | | | | | | |

| Component | | | | | | | | |
|---|---|---|---|---|---|---|---|---|
| (unit: parts by | | Pattern treatment composition | | | | | | |
| weight) | | II-9 | II-10 | II-11 | II-12 | II-13 | II-14 | II-15 |
| Crosslinking | M-1 | — | — | 1.909 | 3.653 | 1.461 | 0.731 | 0.487 |
| agent (M) | M-2 | — | — | — | — | — | — | — |
| | M-3 | 1.218 | 2.435 | — | — | — | — | — |
| Water- | N-1 | 3.653 | 2.436 | — | 1.218 | 3.410 | 4.140 | 4.384 |
| soluble resin | N-2 | — | — | — | — | — | — | — |
| (N) | N-3 | — | — | 0.477 | — | — | — | — |
| Thermal acid | P-1 | 0.039 | — | 0.039 | 0.039 | — | 0.039 | 0.039 |
| generator (P) | P-2 | — | 0.039 | — | — | — | — | — |
| Water (Q) | Q-1 | 95.09 | 95.09 | 97.575 | 95.09 | 95.129 | 95.09 | 95.09 |

| | | | | | | | |
|---|---|---|---|---|---|---|---|
| Crosslinking agent | 25:75 | 50:50 | 80:20 | 75:25 | 30:70 | 15:85 | 10:90 |
| (M):Water-soluble | | | | | | | |
| resin (N) | | | | | | | |

### Examples of Material for Forming Superfine Pattern

The Example 1 to Example 10 and Comparative Example 1 to Comparative Example 8 of materials for forming a superfine pattern are described hereinafter.

### Example 1

The photosensitive resin composition I-1 obtained in the example was coated on a substrate by spin coating method (Spin Coater Model: Mark-Vz, manufactured by Tokyo Electron Limited, rotation speed of about 800 rpm). Then, perform vacuum to 133 Pa, and pre-bake at a temperature of 110° C. on a hot plate for 120 seconds to form a photoresist film with a thickness of 1.5 micrometers. Next, using an exposure machine (Model: FX601, manufactured by Nikon Corporation) to expose the photoresist film with light at 42 J/m². Then, develop for 60 seconds using a tetramethylammonium hydroxide aqueous solution having a concentration of 2.38 weight % as a developer at a temperature of 23° C. Next, post-baking at a temperature of 110° C. on a hot plate for 180 seconds to form a cured product with a width of 4 micrometers at a ratio of 1:1 for exposed and unexposed areas on the substrate.

Then, the pattern treatment composition II-1 obtained in the example was coated on the cured product formed by the photosensitive resin composition I-1 by spin coating method (Spin Coater Model: Mark-Vz, manufactured by Tokyo Electron Limited, rotation speed of about 1700 rpm). Then, bake at a temperature of 70° C. on a hot plate for 120 seconds to dry the pattern treatment composition to form an initial film with a thickness of 0.7 micrometers. Next, bake the initial film at a temperature of 120° C. on a hot plate for 120 seconds to allow the initial film to undergo a crosslinking reaction with the cured product. Then, develop for 70 seconds using a tetramethylammonium hydroxide aqueous solution having a concentration of 2.38 weight % as a developer at a temperature of 23° C. to remove the initial film and pattern treatment composition that did not undergo crosslinking reaction, thereby obtaining a treated pattern. The obtained treated pattern was evaluated by each of the following evaluation methods, and the results are shown in Table 4.

### Example 2 to Example 10 and Comparative Example 1 to Comparative Example 8

The materials for forming a superfine pattern in Example 2 to Example 10 and Comparative Example 1 to Comparative Example 8 were prepared using the same procedure as that in Example 1. The difference is that the types of components and the usage amount thereof in the materials for forming a superfine pattern are changed (as shown in Table 4). The obtained materials for forming a superfine pattern were made into patterns and evaluated by each of the following evaluation methods, and the results are shown in Table 4.

TABLE 4

| | | Examples | | | | | | | | | |
|---|---|---|---|---|---|---|---|---|---|---|---|
| Component | | 1 | 2 | 3 | 4 | 5 | 6 | 7 | 8 | 9 | 10 |
| Photosensitive resin | I-1 | V | V | V | — | V | — | — | V | V | — |
| composition (I) | I-2 | — | — | — | V | | V | V | — | — | V |
| | I-3 | — | — | — | — | — | — | — | — | — | — |
| Pattern treatment | II-1 | V | — | — | — | — | — | — | — | — | — |
| composition (II) | II-2 | — | V | — | — | — | — | — | — | — | — |
| | II-3 | — | — | V | — | — | — | — | — | — | — |
| | II-4 | — | — | — | V | — | — | — | — | — | — |
| | II-5 | — | — | — | — | V | — | — | — | — | — |
| | II-6 | — | — | — | — | — | V | — | — | — | — |
| | II-7 | — | — | — | — | — | — | V | — | — | — |
| | II-8 | — | — | — | — | — | — | — | V | — | — |
| | II-9 | — | — | — | — | — | — | — | — | V | — |
| | II-10 | — | — | — | — | — | — | — | — | — | V |
| | II-11 | — | — | — | — | — | — | — | — | — | — |
| | II-12 | — | — | — | — | — | — | — | — | — | — |
| | II-13 | — | — | — | — | — | — | — | — | — | — |
| | II-14 | — | — | — | — | — | — | — | — | — | — |
| | II-15 | — | — | — | — | — | — | — | — | — | — |
| Evaluation results | Resolution | ◯ | ◯ | Δ | Δ | Δ | Δ | Δ | Δ | Δ | Δ |

| | | Comparative Examples | | | | | | | |
|---|---|---|---|---|---|---|---|---|---|
| Component | | 1 | 2 | 3 | 4 | 5 | 6 | 7 | 8 |
| Photosensitive resin | I-1 | V | V | V | V | V | — | — | — |
| composition (I) | I-2 | — | — | — | — | — | — | — | — |
| | I-3 | — | — | — | — | — | V | V | V |
| Pattern treatment | II-1 | — | — | — | — | — | V | — | — |
| composition (II) | II-2 | — | — | — | — | — | — | V | — |
| | II-3 | — | — | — | — | — | — | — | V |
| | II-4 | — | — | — | — | — | — | — | — |
| | II-5 | — | — | — | — | — | — | — | — |
| | II-6 | — | — | — | — | — | — | — | — |
| | II-7 | — | — | — | — | — | — | — | — |
| | II-8 | — | — | — | — | — | — | — | — |
| | II-9 | — | — | — | — | — | — | — | — |
| | II-10 | — | — | — | — | — | — | — | — |
| | II-11 | V | — | — | — | — | — | — | — |
| | II-12 | — | V | — | — | — | — | — | — |
| | II-13 | — | — | V | — | — | — | — | — |
| | II-14 | — | — | — | V | — | — | — | — |
| | II-15 | — | — | — | — | V | — | — | — |
| Evaluation results | Resolution | ※ | ※ | X | X | X | X | X | X |

### <Evaluation Methods>

a. Resolution

The prepared treated pattern was observed using a field emission-scanning electron microscopy (FE-SEM) (Model: SU8010, manufactured by HITACHI, Ltd.) to examine the width of the cross-sectional shape of the treated pattern. The treated pattern was compared with a cured product having a width of 4 micrometers at a 1:1 ratio of exposed to unexposed areas, and the degree of shrinkage was evaluated for pattern miniaturization. When the shrinkage was within a certain range (for example, greater than 0 micrometers and less than 1 micrometer), it indicated that the material for forming a superfine pattern/pattern treatment composition had good pattern miniaturization capability, i.e., good resolution.

$$shrinkage = \frac{4 - width of cross sectional shape of the treated pattern}{2}$$

The evaluation criteria for resolution are as follows:

$$◦ : 0.6 micrometers ≦ shrinkage < 1 micrometer ;$$

$$△ : 0 micrometer < shrinkage < 0.6 micrometers ;$$

$$\times : shrinkage = 0 micrometer ;$$

$$: 1 micrometer ≦ shrinkage .$$

### <Evaluation Results>

As shown in Table 4, when the material for forming a superfine pattern including a first layer containing a photosensitive resin composition (I) with specific components and a second layer containing a pattern treatment composition (II) with specific components, and the usage amounts of each component are within specific ranges, the Examples used in the formation method of superfine pattern exhibit good superfine pattern forming ability and thus good resolution, which may be applicable to the manufacturing processes of semiconductor device, display device or optical element. In contrast, the Comparative Examples where the material for forming a superfine pattern does not include a first layer containing a photosensitive resin composition (I) with specific components or a second layer containing a pattern treatment composition (II) with specific components show poor resolution when used in the formation method of a superfine pattern.

Furthermore, compared to the pattern treatment compositions where the usage amount of the crosslinking agent (M) is greater than the usage amount of the water-soluble resin (N) (Comparative Examples 1 to 2), the pattern treatment compositions where the usage amount of the crosslinking agent (M) is less than or equal to the usage amount of the water-soluble resin (N) (Examples 1 to 10) exhibit better resolution when used in the formation method of a superfine pattern.

Moreover, compared to the pattern treatment compositions where the weight ratio of the usage amount of the crosslinking agent (M) to the usage amount of the water-soluble resin (N) is not within the range of 20:80 to 50:50 (Comparative Examples 1 to 2, 4 to 5), the pattern treatment compositions where the weight ratio of the usage amount of the crosslinking agent (M) to the usage amount of the water-soluble resin (N) is within the range of 20:80 to 50:50 (Examples 1 to 10) exhibit better resolution when used in the formation method of a superfine pattern.

Furthermore, compared to the pattern treatment composition that does not include a thermal acid generator (P) (Comparative Example 3), the pattern treatment compositions that include a thermal acid generator (P) (Examples 1 to 10) exhibit better resolution when used in the formation method of a superfine pattern.

Moreover, compared to the materials for forming a superfine pattern with photosensitive resin compositions that do not include a hydroxyl-containing additive (C) (Comparative Examples 6 to 8), the material for forming a superfine pattern with photosensitive resin compositions that include a hydroxyl-containing additive (C) (Examples 1 to 10) exhibit better resolution when used in the formation method of a superfine pattern. From this, it may be understood that the pattern treatment composition in the material for forming a superfine pattern is preferably paired with a hydroxyl-containing photosensitive resin composition. As a result, the pattern treatment composition exhibits better resolution when used in the formation method of a superfine pattern.

Based on the above, the material for forming a superfine pattern of the invention includes a first layer containing a photosensitive resin composition (I) with specific components and a second layer containing a pattern treatment composition (II) with specific components, and the usage amounts of each component are within specific ranges, it enables the material for forming a superfine pattern to have good superfine pattern forming ability when used in the formation method of superfine pattern, thereby exhibiting good resolution. As a result, it may be applicable to the manufacturing processes of semiconductor devices, display devices, or optical elements, and may improve the performance of the formed devices or elements. Furthermore, the photosensitive resin composition and the pattern treatment composition in the material for forming a superfine pattern of the invention may be used separately. When the pattern treatment composition of the invention includes specific components and the usage amounts of each component are within specific ranges, it exhibits good resolution when used in the formation method of superfine pattern (for which the pattern is formed by hydroxyl-containing photosensitive resin composition), making it applicable to the manufacturing processes of semiconductor devices, display devices, or optical elements.

Although the invention has been disclosed in the embodiments above, they are not intended to limit the invention. Anyone with ordinary knowledge in the relevant technical field can make changes and modifications without departing from the spirit and scope of the invention. The scope of protection of the invention shall be subject to those defined by the claims attached.

What is claimed is:

1. A material for forming a superfine pattern, comprising:
a first layer, comprising a photosensitive resin composition (I), the photosensitive resin composition (I) comprises an alkali-soluble phenol formaldehyde resin (A), a sensitizer (B), a hydroxyl-containing additive (C) and an organic solvent (D); and
a second layer, comprising a pattern treatment composition (II), the pattern treatment composition (II) comprises a crosslinking agent (M), a water-soluble resin (N), a thermal acid generator (P) and water (Q);
wherein the hydroxyl-containing additive (C) comprises a compound represented by the following Formula (C-1),
the crosslinking agent (M) comprises a melamine-based crosslinking agent,
based on 100 parts by weight of the alkali-soluble phenol formaldehyde resin (A) in the photosensitive resin composition (I), a usage amount of the sensitizer (B) is 10 parts by weight to parts by weight, a usage amount of the hydroxyl-containing additive (C) is 2 parts by weight to 15 parts by weight, and a usage amount of the organic solvent (D) is 400 parts by weight to 1200 parts by weight,
based on a total usage amount of the pattern treatment composition (II) being 100 parts by weight, a usage amount of the crosslinking agent (M) is 0.5 parts by weight to 2.5 parts by weight, a usage amount of the water-soluble resin (N) is 2.4 parts by weight to 4.5 parts by weight, a usage amount of the thermal acid generator (P) is 0.02 parts by weight to 0.06 parts by weight, and a usage amount of the water (Q) is 90 parts by weight to 98 parts by weight: 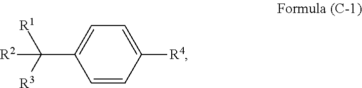
In Formula (C-1),
R¹ to R³ each represents hydrogen, an alkyl group having 1 to 3 carbon atoms, a phenyl group substituted with hydroxyl group or a derivative thereof,
R⁴ represents a hydroxyl group, an alkyl group having 1 to 3 carbon atoms, a phenyl group substituted with hydroxyl and/or alkyl groups or a derivative thereof, and
at least one of R¹ to R⁴ represents a hydroxyl-containing substituent.

2. The material for forming a superfine pattern according to claim 1, wherein a weight average molecular weight of the alkali-soluble phenol formaldehyde resin (A) in the photosensitive resin composition (I) is 2000 g/mol to 20000 g/mol.

3. The material for forming a superfine pattern according to claim 1, wherein the sensitizer (B) in the photosensitive resin composition (I) comprises a compound having a quinonediazide group, a hydroxy benzophenone-based compound, a hydroxy aryl-based compound, or a combination thereof.

4. The material for forming a superfine pattern according to claim 1, wherein in the pattern treatment composition (II), a usage amount of the crosslinking agent (M) is less than or equal to a usage amount of the water-soluble resin (N).

5. The material for forming a superfine pattern according to claim 1, wherein in the pattern treatment composition (II), a weight ratio of a usage amount of the crosslinking agent (M) to a usage amount of the water-soluble resin (N) is 20:80 to 50:50.

6. The material for forming a superfine pattern according to claim 1, wherein the crosslinking agent (M) in the pattern treatment composition (II) comprises a compound represented by the following Formula (M-1): 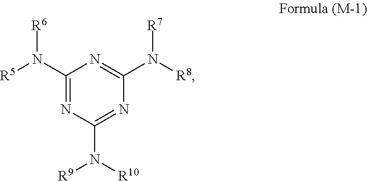
in Formula (M-1), R⁵ to R¹⁰ each represents hydrogen, an alkyl group, or an ether-containing substituent, wherein at least one of R⁵ to R¹⁰ is an ether-containing substituent.

7. The material for forming a superfine pattern according to claim 1, wherein the water-soluble resin (N) in the pattern treatment composition (II) comprises a polymer represented by the following Formula (N-1): 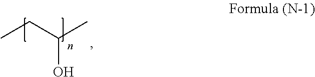
in Formula (N-1), n represents an integer from 1000 to 3000.

8. The material for forming a superfine pattern according to claim 1, wherein a weight average molecular weight of the water-soluble resin (N) is 40000 g/mol to 120000 g/mol.

9. The material for forming a superfine pattern according to claim 1, wherein the thermal acid generator (P) comprises an ionic thermal acid generator.

10. A photosensitive resin composition for a material for forming a superfine pattern, comprising:
an alkali-soluble phenol formaldehyde resin (A);
a sensitizer (B);
a hydroxyl-containing additive (C); and
an organic solvent (D),
wherein the hydroxyl-containing additive (C) comprises a compound represented by the following Formula (C-1),
based on 100 parts by weight of the alkali-soluble phenol formaldehyde resin (A) in the photosensitive resin composition, a usage amount of the sensitizer (B) is 10 parts by weight to 35 parts by weight, a usage amount of the hydroxyl-containing additive (C) is 2 parts by weight to 15 parts by weight, and a usage amount of the organic solvent (D) is 400 parts by weight to 1200 parts by weight: 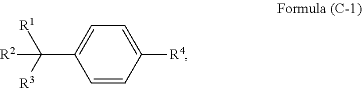
in Formula (C-1),
R¹ to R³ each represents hydrogen, an alkyl group having 1 to 3 carbon atoms, a phenyl group substituted with hydroxyl group or a derivative thereof,
R⁴ represents a hydroxyl group, an alkyl group having 1 to 3 carbon atoms, a phenyl group substituted with hydroxyl and/or alkyl groups or a derivative thereof, and
at least one of R¹ to R⁴ represents a hydroxyl-containing substituent.

11. The photosensitive resin composition according to claim 10, wherein a weight average molecular weight of the alkali-soluble phenol formaldehyde resin (A) is 2000 g/mol to 20000 g/mol.

12. The photosensitive resin composition according to claim 10, wherein the sensitizer (B) comprises a compound having a quinonediazide group, a hydroxy benzophenone-based compound, a hydroxy aryl-based compound, or a combination thereof.

13. A pattern treatment composition for a material for forming a superfine pattern, comprising:
a crosslinking agent (M), comprising a melamine-based crosslinking agent;
a water-soluble resin (N);
a thermal acid generator (P); and
water (Q),
wherein based on a total usage amount of the pattern treatment composition being 100 parts by weight, a usage amount of the crosslinking agent (M) is 0.5 parts by weight to 2.5 parts by weight, a usage amount of the water-soluble resin (N) is 2.4 parts by weight to 4.5 parts by weight, a usage amount of the thermal acid generator (P) is 0.02 parts by weight to 0.06 parts by weight, and a usage amount of the water (Q) is 90 parts by weight to 98 parts by weight.

14. The pattern treatment composition according to claim 13, wherein a usage amount of the crosslinking agent (M) is less than or equal to a usage amount of the water-soluble resin (N).

15. The pattern treatment composition according to claim 13, wherein a weight ratio of a usage amount of the crosslinking agent (M) to a usage amount of the water-soluble resin (N) is 20:80 to 50:50.

16. The pattern treatment composition according to claim 13, wherein the crosslinking agent (M) comprises a compound represented by the following Formula (M-1): 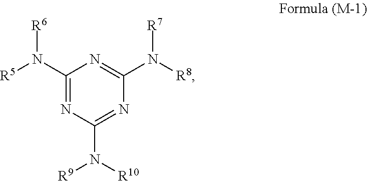
in Formula (M-1), R⁵ to R¹⁰ each represents hydrogen, an alkyl group, or an ether-containing substituent, wherein at least one of R⁵ to R¹⁰ is an ether-containing substituent.

17. The pattern treatment composition according to claim 13, wherein the water-soluble resin (N) comprises a polymer represented by the following Formula (N-1): 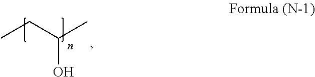
in Formula (N-1), n represents an integer from 1000 to 3000.

18. The pattern treatment composition according to claim 13, wherein a weight average molecular weight of the water-soluble resin (N) is 40000 g/mol to 120000 g/mol.

19. The pattern treatment composition according to claim 13, wherein the thermal acid generator (P) comprises an ionic thermal acid generator.

20. A formation method of a superfine pattern, comprising:
applying the material for forming a superfine pattern according to claim 1 on a substrate; and
cleaning with a solvent.

21. The formation method of a superfine pattern according to claim 20, further comprising:
applying the photosensitive resin composition from the material for forming a superfine pattern on the substrate to form a cured product; and
applying the pattern treatment composition from the material for forming a superfine pattern on the cured product.

22. A formation method of a superfine pattern, comprising:
forming a cured product on a substrate, wherein the cured product is formed from the photosensitive resin composition according to claim 10;
coating a pattern treatment composition on the cured product; and
cleaning with a solvent.

23. A formation method of a superfine pattern, comprising:
forming a cured product on a substrate, wherein the cured product is formed from a photosensitive resin composition;
coating the pattern treatment composition according to claim 13 on the cured product; and
cleaning with a solvent.
